(19) United States
(12) Patent Application Publication
(10) Pub. No.: US 2026/0241675 A1
(43) Pub. Date: Aug. 20, 2026

(54) METHOD OF LAMINATING AN INTERPOSER FOR DIE TRANSFER SUBSTRATES

(71) Applicant: Applied Materials, Inc., Santa Clara, CA (US)

(72) Inventors: Mahendran CHIDAMBARAM, Saratoga, CA (US); Uma SRIDHAR, Sunnyvale, CA (US); Peiwen LIU, Fremont, CA (US); Raanan ZEHAVI, Santa Clara, CA (US); Hou T. NG, Campbell, CA (US); Visweswaren SIVARAMAKRISHNAN, Cupertino, CA (US); Nag B. PATIBANDLA, Santa Clara, CA (US)

(21) Appl. No.: 19/159,484

(22) PCT Filed: Feb. 26, 2024
(86) PCT No.: PCT/US2024/017220

§ 371 Date: Aug. 25, 2025

Related U.S. Application Data
(60) Provisional application No. 63/490,351, filed on Mar. 15, 2023.

(51) Int. Cl. B32B 38/00; B32B 37/00; B32B 37/22; B32B 37/26; B32B 39/00; H10H 29/03

(52) U.S. Cl. CPC B32B 38/0004; B32B 37/0053; B32B 37/223; B32B 37/26; B32B 39/00; H10H 29/03; B32B 2307/7376; B32B 2457/206

(57) ABSTRACT

Embodiments of the present disclosure generally relate to LED pixels and methods of fabricating LED pixels. The device includes a lamination module. The lamination module includes a polymer film roll configured to supply a polymer film to the lamination module, a bottom liner recovery roller, a top liner recovery roller, a cutting mechanism, a substrate source, a conveyor system, and a plurality of film rollers. The polymer film includes one or more polymer layers, a top liner, and a bottom liner. The cutting mechanism is configured to cut the one or more polymer layers and the top liner. The cutting mechanism comprises a first blade and a second blade. A space between the first blade and the second blade is less than about 10 cm. The substrate source is configured to supply a substrate.

### BACKGROUND

### Field

Embodiments of the present disclosure generally relate to micro-LED displays and methods of fabricating micro-LED displays. In particular, the disclosure relates to laminating interposers for die transfer substrates.

### Description of the Related Art

A light emitting diode (LED) panel uses an array of LEDs, with individual LEDs providing the individually controllable pixel elements. Such an LED panel can be used for a computer, touch panel device, personal digital assistant (PDA), cell phone, television monitor, and the like.

An LED panel that uses micron-scale LEDs based on III-V semiconductor technology (also called micro-LEDs) would have a variety of advantages as compared to OLEDs, e.g., higher energy efficiency, brightness, and lifetime, as well as fewer material layers in the display stack, which can simplify manufacturing. However, there are challenges to fabrication of micro-LED panels. Micro-LEDs having different color emission (e.g., red, green and blue pixels) need to be fabricated on different substrates through separate processes. The fabrication process requires parallel die transfer from a growth sapphire substrate to integrated thin film transistor backplanes, with high mechanical and light-up yields. Due to the complexity in die transfer technology, the structural integrity of the interposer and the method of applying the interposer to a supporting substrate are critical. Defects such as entrapment of bubbles/particles or insufficient laminated film quality (e.g., lack of film uniformity or film edge smoothness) are detrimental to achieving high yield transfers.

Therefore, what is needed in the art is a method for laminating interposers for die transfer substrates.

### SUMMARY

In one embodiment, a device is provided. The device includes a lamination module. The lamination module includes a polymer film roll configured to supply a polymer film to the lamination module, a bottom liner recovery roller, a top liner recovery roller, a cutting mechanism, a substrate source, a conveyor system, and a plurality of film rollers. The polymer film includes one or more polymer layers, a top liner, and a bottom liner. The cutting mechanism is configured to cut the one or more polymer layers and the top liner. The cutting mechanism comprises a first blade and a second blade. A space between the first blade and the second blade is less than about 10 cm. The substrate source is configured to supply a substrate.

In another embodiment, a method is provided. The method includes supplying a polymer film to a lamination module, removing the bottom liner from the polymer film, supplying a substrate to a conveyor system of the lamination module, cutting the one or more polymer layers and the top liner with a cutting mechanism, laminating the substrate with the polymer film, and removing the top liner from the polymer film. The polymer film comprises a bottom liner, a top liner, and one or more polymer layers. The cutting mechanism comprises a first blade and a second blade. A space between the first blade and the second blade is less than about 10 cm.

In yet another embodiment, a lamination system is disclosed. The lamination system includes a lamination module, a substrate source, a substrate receiver, and a conveyor system. The lamination module includes a bottom liner recovery roller, a top liner recovery roller, a cutting mechanism configured to cut one or more polymer layers and the top liner, and a plurality of film rollers. The cutting mechanism includes a first blade and a second blade. A space between the first blade and the second blade is less than about 10 cm. A polymer film roll is configured to supply a polymer film to the lamination module. The polymer film includes one or more polymer layers, a top liner, and a bottom liner. The substrate source is configured to supply a substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and may admit to other equally effective embodiments.

FIG. 1 is a schematic, perspective view of a lamination module, according to embodiments.

FIG. 2 is a schematic, cross-sectional view of a polymer film, according to embodiments.

FIG. 3 is a schematic, cross-sectional view of a laminated substrate, according to embodiments.

FIG. 4 is a flow diagram of a method of laminating a substrate, according to embodiments.

FIG. 5A-5H is a schematic, cross-sectional view of a polymer film roll during a method of laminating a substrate, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to micro-LED displays and methods of fabricating micro-LED displays. In particular, the disclosure relates to laminating interposers for die transfer substrates. A lamination module includes a polymer film roll configured to supply a polymer film to the lamination module. A bottom liner recovery roller collects a bottom liner of the polymer film, and a top liner recovery roller collects a top liner of the polymer film. A cutting mechanism is configured to cut the one or more polymer layers and the top liner. The cutting mechanism includes a first blade and a second blade. A space between the first blade and the second blade is less than about 10 cm. The substrate is supplied by a substrate source.

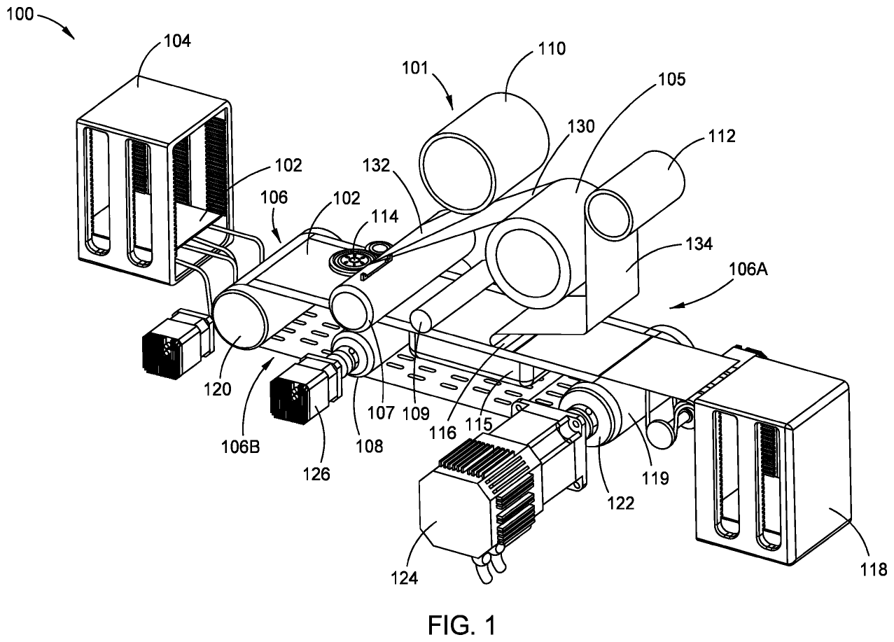

FIG. 1 is a schematic, perspective view of lamination system 100. The lamination system 100 includes a substrate source (e.g., a first substrate elevator 104), a polymer film roll 105, a lamination module 101, a conveyor system 106, a substrate support platen 115, and a substrate receiver (e.g., a second substrate elevator 118). The lamination module 101 includes a plurality of film rollers including a first film roller 107, a second film roller 108, and a third film roller 109, a bottom liner recovery roller 110, a top liner recovery roller 112, and a cutting mechanism 114. The cutting mechanism 114 includes a blade 116 (or one or more blades 116). The first substrate elevator 104 is configured to supply a substrate 102 to an upper side of the conveyor system 106. The conveyor system 106 includes a conveyor belt 119, a first conveyor roller 120, a second conveyor roller 122, and a first conveyor motor 124. The conveyor belt 119 spans between the first conveyor roller 120 and the second conveyor roller 122. The second conveyor roller 122 is coupled to the first conveyor motor 124. The first conveyor motor 124 is configured to rotate the second conveyor roller 122, which is subsequently configured to rotate the conveyor belt 119.

The polymer film roll 105 is configured to supply a polymer film 130 to the lamination module 101. The bottom liner recovery roller 110 is configured to recover a bottom liner 132. The top liner recovery roller 112 is configured to recover a top liner 134. The first film roller 107 and the second film roller 108 are disposed on opposite sides on the conveyor belt 119 on the upper side of the conveyor system 106. A second motor 126 is configured to rotate the second film roller 108. The third film roller 109 and substrate support platen 115 are disposed on opposite sides of the conveyor belt 119 on the upper side 106A of the conveyor system 106. The first film roller 107, second film roller 108, third film roller 109, and substrate support platen 115 are configured to press the polymer film 130 onto the substrate 102. The first film roller 107, second film roller 108, and third film roller 109 may include a material such as Teflon, polyurethane, other rubber materials, or stainless steel. The second substrate elevator 118 is configured to collect the substrates 102 from the conveyor system 106.

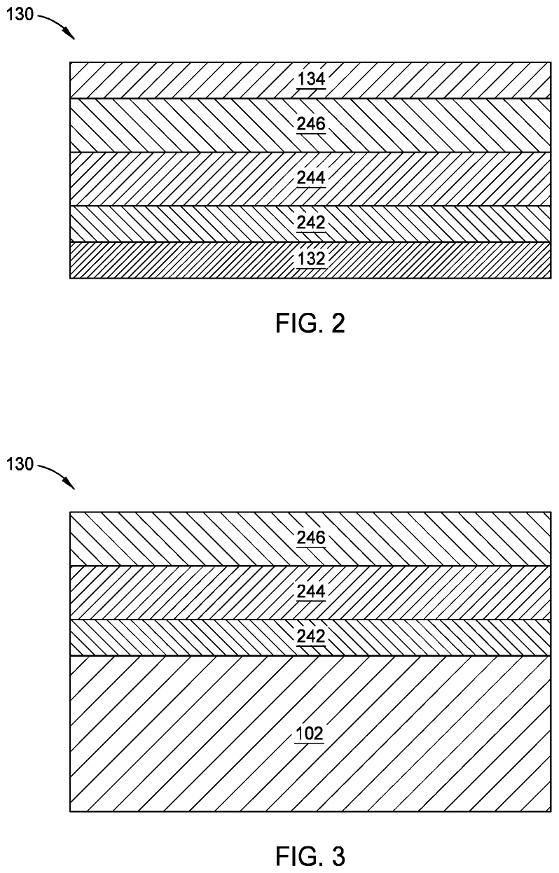

The cutting mechanism 114 may be configured to cut into the polymer film 130. The cutting mechanism 114 may have one or more blades. The cutting mechanism 114 may be a rotary cutting mechanism, an ultrasonication assisted cutting system, or a laser cutting mechanism. The blades of the cutting mechanism 114 pierce through one or more polymer film layers (as described in FIG. 2) of the polymer film 130 and a portion of the top liner 134. The blades cut into about 1% to about 20% of the thickness of the top liner. By cutting into a portion of the top liner 134, the continuous integrity of the top liner 134 is maintained for the top liner recovery roller 112 to effectively collect the top liner 134 without breaking the top liner 134. Additionally, by piercing the top liner 134, the cutting mechanism 114 ensures clean separation of the one or more polymer layers from the top liner 134.

The conveyor belt 119 moves in a first direction from the first substrate elevator 104 towards the second substrate elevator 118 on the upper side 106A of the conveyor system 106. The conveyor belt 119 moves in a second direction from the second substrate elevator 118 towards the first substrate elevator 104 on a lower side 106B of the conveyor system 106. The substrate 102 moves in the first direction on the upper side of the conveyor system 106.

FIG. 2 is a schematic, cross-sectional view of the polymer film 130. The polymer film 130 is supplied to the lamination module 101 from the polymer film roll 105. FIG. 3 is a schematic, cross-sectional view of the polymer film 130 disposed on the substrate 102. The polymer film 130 includes a bottom liner 132, one or more polymer layers, and a top liner 134. The one or more polymer layers may include an adhesive layer 242, a supporting base polymer 244, and a polymer layer 246. The bottom liner 132 and the top liner 134 are configured to prevent the polymer film 130 from adhering to itself when the polymer film 130 is rolled onto the polymer film roll 105, the top liner 124 and the bottom liner 132. The adhesive layer 242 is disposed over the bottom liner 132. The adhesive layer 242 is configured to adhere the polymer film 130 to the substrate 102. The adhesive layer 242 may include materials such as polyamides, polyesters, ethylene-vinyl acetate, polyurethanes, polyamides epoxies, natural and synthetic rubbers, thermoplastic elastomers, polyacrylates, polyvinyl alkyl ethers, silicones, polyacrylates, fluoropolymers or combinations thereof. The supporting base polymer 244 is disposed over the adhesive layer 242. The supporting base polymer 244 may include materials such as polyamides, polyesters, ethylene-vinyl acetate, polyurethanes, polyamides epoxies, natural and synthetic rubbers, thermoplastic elastomers, polyacrylates, polyvinylalkyy ethers, silicones, polyacrylates, fluoropolymers, pressure-sensitive adhesives, polyimides, PPS, or combination thereof. The polymer layer 246 is disposed over the supporting base polymer 244. The polymer layer 246 includes thermal release tapes, UV release tapes, light and laser release tapes, or combinations thereof. The top liner 134 is disposed over the polymer layer 246.

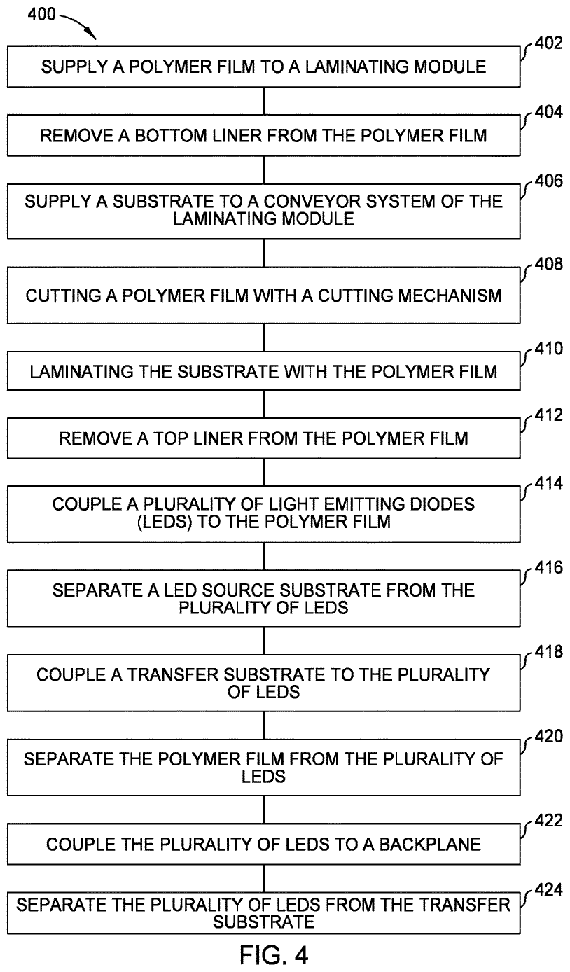

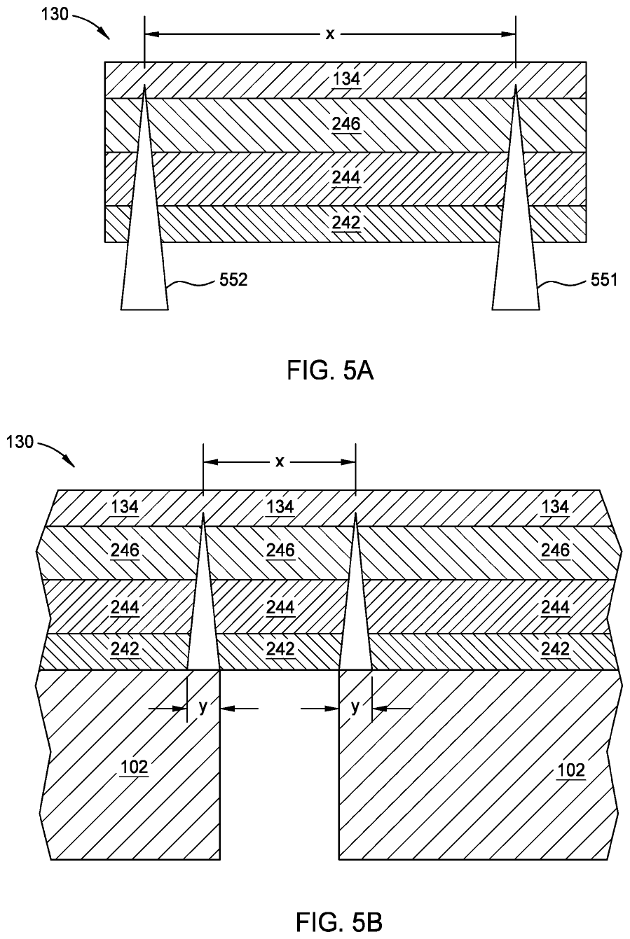

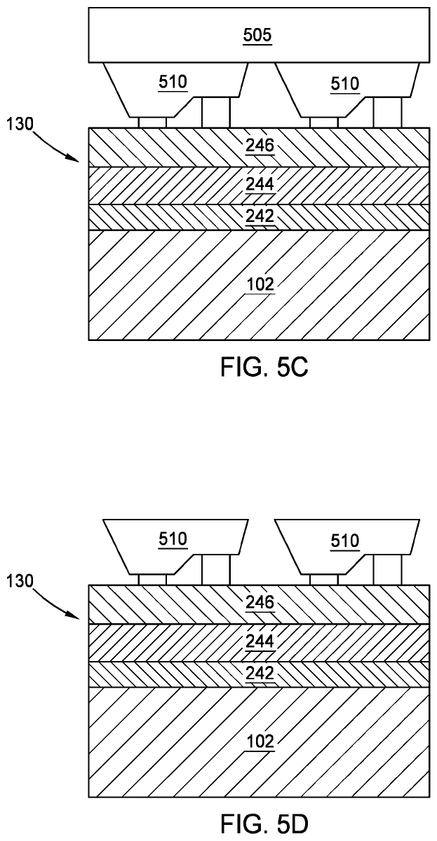

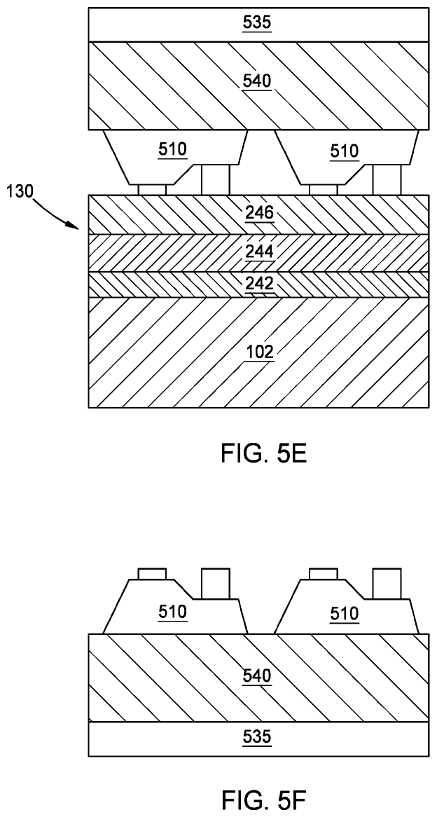

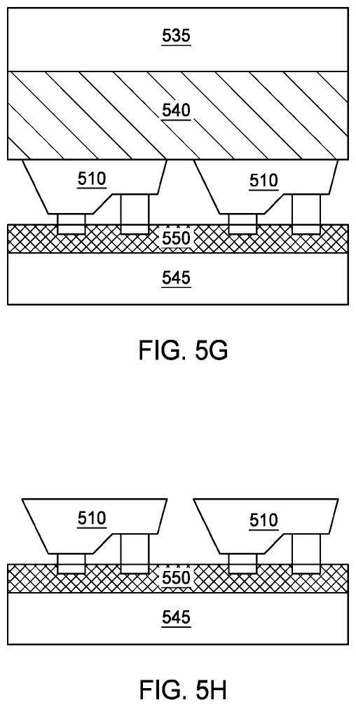

FIG. 4 is a flow diagram of a method 400 of laminating a substrate 102. FIG. 5A-5H are schematic, cross-sectional views of a polymer film 130 during the method 400 of laminating the substrate 102. At operation 402, the polymer film 130 is supplied to the lamination module 101. The polymer film 130 is fed to the lamination module 101 from a polymer film roll 105. As shown in FIG. 2, the polymer film 130 includes a bottom liner 132, a top liner 134, and one or more polymer layers. The one or more polymer layers may include an adhesive layer 242, a supporting base polymer 244, and a polymer layer 246.

At operation 404, the bottom liner 132 is removed from the polymer film 130. The bottom liner 132 is removed using a bottom liner recovery roller 110. By removing the bottom liner 132, the one or more polymer layers (e.g., the adhesive layer 242) becomes exposed.

At operation 406, a substrate 102 is supplied to a conveyor system 106 of the lamination module 101. The substrate 102 is supplied to the conveyor system 106 from a first substrate elevator 104. The conveyor system 106 includes a conveyor belt 119, a first conveyor roller 120, a second conveyor roller 122, and a first conveyor motor 124. The first conveyor motor 124 rotates the second conveyor roller 122 to move the conveyor belt 119 in a first direction along an upper side 106A of the conveyor system 106 and in a second direction along a lower side 106B of the conveyor system 106. The first direction goes from the first substrate elevator 104 to a second substrate elevator 118, and the second direction goes from the second substrate elevator 118 to the first substrate elevator 104. The substrate 102 is disposed on the conveyor belt 119 of the conveyor system 106 and travels in the first direction.

At operation 408, as shown in FIG. 5A, the polymer film 130 is cut using a cutting mechanism 114. The cutting mechanism 114 may have one or more blades. The cutting mechanism 114 may be a rotary cutting mechanism, an ultrasonication assisted cutting system, or a laser cutting mechanism. As shown in FIG. 5A, the cutting mechanism 114 has a first blade 551 and a second blade 552. The blades are spaced a distance x apart. The distance x is less than about 10 cm, such as less than about 1 cm, such as 0 cm (e.g., a single cut from a single blade). The blades pierce the adhesive layer 242, the supporting base polymer 244, the polymer layer 246, and a portion of the top liner 134. The blades cut into about 1% to about 20% of the thickness of the top liner 134. By piercing a portion of the top liner 134, the continuous integrity of the top liner 134 is maintained while allowing clean separation of the adhesive layer 242, the supporting base polymer 244, and the polymer layer 246 from the top liner 134.

At operation 410, as shown in FIG. 5B, the substrate 102 is laminated by the polymer film 130. A first film roller 107 guides the polymer film 130 to the substrate 102 on the conveyor belt 119. The first film roller 107 is positioned above the conveyor belt 119 on the upper side 106A of the conveyor system 106 and a second film roller 108 is positioned below the conveyor belt 119 on the upper side 106A of the conveyor system 106, opposite the first film roller 107. The exposed adhesive layer 242 is pressed against the substrate 102 using the first film roller 107 and the second film roller 108. A third film roller 109 and a substrate support platen 115 are positioned after the first film roller 107 and second film roller 108 in the first direction. The third film roller 109 and the substrate support platen 115 continue to press the adhesive layer 242 against the substrate 102 to eliminate defects at an adhesion interface. The top liner 134 prevents the polymer layers of the polymer film 130 from adhering to the first film roller 107, the second film roller 108, the third film roller 109, and the substrate support platen 115. As shown in FIG. 5B, the polymer film 130 may have a clearance gap y from the edges of the substrate 102. The distance x between the cutting blades is maintained to allow for the clearance gap y, while taking into consideration the tapered geometry of the blades. The clearance gap y is less than about 10 cm, such as less than about 1 cm, such as about 0 cm. A portion of the adhesive layer 242, the supporting base polymer 244, and the polymer layer 246 is not pressed against the substrate 102 (e.g., the portion of the adhesive layer 242, the supporting base polymer 244, and the polymer layer 246 is in a gap from a leading substrate 102 to the trailing substrate 102). The gap between the leading substrate 102 and the trailing substrate 102 may be equal to the distance x between the first blade 551 and the second blade 552.

At operation 412, the top liner 134 is removed from the polymer film 130. A blade doctor may be used to peel the top liner 134 from the polymer film 130. The top liner 134 is recovered using the top liner recovery roller 112. The portion of the adhesive layer 242, the supporting base polymer 244, and the polymer layer 246 that is not laminated onto a substrate 102 may also be recovered by the top liner recovery roller 112. Since the top liner 134 was not severed during operation 408, the continuous integrity of the top liner 134 is maintained for the top liner recovery roller 112 to effectively collect the top liner 134 without breaking the top liner 134. By removing the bottom liner 132, the polymer layer 246 becomes exposed to further processing.

At operation 414, as shown in FIG. 5C, a plurality LEDs 510 are coupled to the polymer film 130. A LED source substrate 505 has the plurality LEDs 510 formed or grown thereon. Although only 2 LEDs 510 are illustrated, it is to be understood that a substrate may have hundreds, thousands, millions, or more LEDs formed, and which may be any size, as the present technology may encompass micro-LEDs among any other types of LED structure. The LED source substrate 505 may be any substrate on which structures may be formed, such as silicon materials, aluminum materials, including sapphire, or any other materials as may be used in display or semiconductor fabrication. The LEDs 510 may be characterized by any shape or structure, and may be formed as monochromatic LED structures, or specific RGB or other LED structures. As illustrated, the LED structures may have a stepped profile as illustrated, or any other structure. One or more contacts may be formed or may extend from the LEDs 510. For example, a first contact, such as an N-contact, and a second contact, such as a P-contact may extend from the first surface of the LED. The contacts may be made of any metal, alloy, or conductive material in embodiments encompassed by the present technology. The contacts may be formed to a substantially similar height, although variation may occur among the LEDs formed across the substrate.

At operation 416, as shown in FIG. 5D, the LED source substrate 505 is separated from the LEDs 510. After the first coupling material is sufficiently applied and/or cured, the LED source substrate 505 may be separated from the plurality of fabricated LEDs 510. Any number of separation techniques may be performed including mechanical and energy-enhanced separation. As one non-limiting example, in some embodiments a laser lift-off process may be performed. As noted above, although LED source substrate 505 may be any number of materials, in some embodiments LED source substrate 505 may be sapphire. The separation process may include directing a laser through the backside of the LED source substrate 505 to decouple the plurality of fabricated LEDs 510 from the LED source substrate 505.

At operation 418, as shown in FIG. 5E, a transfer substrate 535 is coupled to the plurality of LEDs 510. Once the LED source substrate 505 has been separated from the plurality of LEDs 510, the plurality of fabricated LEDs 510 may be inverted with respect to the polymer film 130. The transfer substrate 525 may include a coupling material 240, which may extend along a second surface or backside of each LED 510 of the plurality of LEDs 510, and may extend between the transfer substrate 535 and the LEDs 510. The transfer substrate 535 may be or include any of the materials previously described, including glass, a silicon-containing material, a polymeric or plastic material, or any other substrate on which semiconductor or display processing may occur. The transfer substrate 535 may a material that is thermally compatible with a backplane substrate.

At operation 420, as shown in FIG. 5F, the polymer film 130 may be separated from the transfer substrate 535, which may expose the metal contacts on the LEDs 510. The LEDs 510 may be retained on the coupling material 540 associated with transfer substrate 535.

At operation 422, as shown in FIG. 5G, the plurality of LEDs 510 are coupled to a backplane 550. After the polymer film 130 is separated from the transfer substrate 535, a bonding operation may be performed. The transfer substrate 535 may be used to align LEDs 510 with a backplane 550 for a display, and which may be formed on a substrate 545. The contacts of the LEDs 510 may be aligned with corresponding contacts of the backplane 550. A bonding process may be performed, which may include, among any number of bonding operations, forming a eutectic bond between the contact materials if different, or forming a solid connection between the contacts. As one non-limiting example, the LED contacts may be or include indium, which may melt at about 156° C. by applying heat to the substrate 545, the contact connection may be raised above the melting point of the contacts, which may bond the contacts. As noted previously, this may cause both the backplane substrate 545 and the transfer substrate 535 to be heated. Based on the coefficient of thermal expansion of the substrate materials, the substrates may expand to different degrees, which may impact alignment during the bonding process, and can reduce yield for the LED connections. Similarly, pressure may be applied to the one or both substrates during the bonding process, which may lower the melting temperature of the contact materials, and may ensure the bonding may be performed below the release onset temperature of the second coupling material.

At operation 224, the plurality of LEDs 510 are separated from the transfer substrate 535. The transfer substrate 235 may be removed from the plurality of LEDs 510 by releasing the coupling material 540 from the second surface or backside of the LEDS 510.

In summary, a lamination module includes a polymer film roll configured to supply a polymer film to the lamination module. A bottom liner recovery roller collects a bottom liner of the polymer film, and a top liner recovery roller collects a top liner of the polymer film. A cutting mechanism is configured to cut the one or more polymer layers and a portion of the top liner. By piercing a portion of the top liner, the continuous integrity of the top liner is maintained while allowing clean separation of the polymer film from the top liner.

While the foregoing is directed to embodiments of the present disclosure, other and further embodiments of the disclosure may be devised without departing from the basic scope thereof, and the scope thereof is determined by the claims that follow.

What is claimed is:

1. A lamination module, comprising:
a bottom liner recovery roller;
a top liner recovery roller; and
a cutting mechanism configured to cut one or more polymer layers and a top liner of a polymer film supplied by a polymer film roll, and wherein the cutting mechanism comprising a first blade and a second blade, wherein a space between the first blade and the second blade is less than about 10 cm.

2. The lamination module of claim 1, wherein the cutting mechanism is configured to cut about 1% to about 20% of a thickness of the top liner.

3. The lamination module of claim 1, wherein a plurality of film rollers are configured to laminate a substrate with the polymer film.

4. The lamination module of claim 3, wherein the plurality of film rolls comprises:
a first film roller;
a second film roller; and
a third film roller.

5. The lamination module of claim 3, wherein the first blade and the second blade have a tapered geometry, wherein the tapered geometry and the space between the first blade and the second blade are configured to allow a clearance gap between an edge of the substrate and the polymer film.

6. The lamination module of claim 1, wherein the one or more polymer layers includes an adhesive layer, a supporting base polymer, and a polymer layer.

7. The lamination module of claim 1, wherein The lamination module of claim 1, wherein the cutting mechanism comprises a rotary cutting mechanism, an ultrasonication assisted cutting system, or a laser cutting mechanism.

8. A method of laminating a substrate, comprising:
supplying a polymer film to a lamination module, wherein the polymer film comprises a bottom liner, a top liner, and one or more polymer layers;
removing the bottom liner from the polymer film;
supplying a substrate to a conveyor system of the lamination module;
cutting the one or more polymer layers and the top liner with a cutting mechanism, wherein the cutting mechanism comprises a first blade and a second blade, wherein a space between the first blade and the second blade is less than about 10 cm;
laminating the substrate with the polymer film; and
removing the top liner from the polymer film.

9. The method of claim 8, further comprising cutting from about 1% to about 20% of a thickness of the top liner with the cutting mechanism.

10. The method of claim 8, wherein a plurality of film rollers are configured to laminate the substrate with the polymer film.

11. The method of claim 8, wherein the first blade and the second blade have a tapered geometry, wherein the tapered geometry and the space between the first blade and the second blade are configured to allow a clearance gap between an edge of the substrate and the polymer film.

12. The method of claim 8, wherein the one or more polymer layers includes an adhesive layer, a supporting base polymer, and a polymer layer.

13. The method of claim 8, wherein a clearance gap is less than about 10 cm.

14. The method of claim 8, wherein the cutting mechanism comprises a rotary cutting mechanism, an ultrasonication assisted cutting system, or a laser cutting mechanism.

15. A lamination system, comprising:
a lamination module, comprising:
a bottom liner recovery roller;
a top liner recovery roller;
a cutting mechanism configured to cut one or more polymer layers and the top liner, the cutting mechanism comprising a first blade and a second blade, wherein a space between the first blade and the second blade is less than about 10 cm; and
a plurality of film rollers;
a polymer film roll configured to supply a polymer film to the lamination module, wherein the polymer film includes one or more polymer layers, a top liner, and a bottom liner;
a substrate source configured to supply a substrate;
a substrate receiver; and
a conveyor system.

16. The lamination system of claim 15, wherein the cutting mechanism is configured to cut about 1% to about 20% of a thickness of the top liner.

17. The lamination system of claim 15, wherein the plurality of film rollers are configured to laminate a substrate with the polymer film.

18. The lamination system of claim 17, wherein the first blade and the second blade have a tapered geometry, wherein the tapered geometry and the space between the first blade and the second blade are configured to allow a clearance gap between an edge of the substrate and the polymer film.

19. The lamination system of claim 15, wherein the one or more polymer layers includes an adhesive layer, a supporting base polymer, and a polymer layer.

20. The lamination system of claim 15, wherein the cutting mechanism comprises a rotary cutting mechanism, an ultrasonication assisted cutting system, or a laser cutting mechanism.
